(19) United States
(12) Patent Application Publication
(10) Pub. No.: US 2011/0226182 A1
(43) Pub. Date: Sep. 22, 2011

(54) CRUCIBLE, CRYSTAL PRODUCTION DEVICE, AND HOLDER

(75) Inventors: Makoto Sasaki, Itami-shi (JP); Shin Harada, Osaka-shi (JP); Taro Nishiguchi, Itami-shi (JP)

(73) Assignee: SUMITOMO ELECTRIC INDUSTRIES, LTD., Osaka-shi (JP)

(21) Appl. No.: 13/049,069

(22) Filed: Mar. 16, 2011

(30) Foreign Application Priority Data
Mar. 18, 2010 (JP) 2010-062306

(51) Int. Cl. C30B 23/02

(52) U.S. Cl. 118/726

(57) ABSTRACT

A crucible includes a body portion having a hollow inner portion, and a projection portion connected to an inner circumferential surface of the body portion and projecting toward the inner portion. The projection portion has a side surface provided with a thread. A holder includes a base and a protrusion connected to an end portion of the base. The protrusion has an inner circumferential side provided with a thread. A crystal production device includes the crucible and the holder. The holder is attached to the projection portion of the crucible by means of the threads formed in the holder and the crucible.

### BACKGROUND OF THE INVENTION

1. Field of the Invention

The present invention relates to a crucible, a crystal production device, and a holder, more particularly, relates to a crucible, a crystal production device, and a holder, each of which is used to produce silicon carbide (SiC) crystal.

2. Description of the Background Art

SiC crystal has a large band gap, and has a larger maximum field for dielectric breakdown and a larger heat conductivity than those of silicon (Si). In addition, it has a carrier mobility as large as that of Si, and has a large electron saturation drift velocity and a large breakdown voltage. Hence, it is expected to apply such SiC crystal to semiconductor devices, which are required to achieve high efficiency, high breakdown voltage, and large capacity.

The SiC crystal used for such semiconductor devices or the like is produced by means of a sublimation method in a vapor growth method as disclosed in, for example, U.S. Pat. No. 7,351,286 (Patent Document 1).

Patent Document 1 disclose a SiC crystal production device including a holder, having a threaded upper portion, for a seed substrate, and a crucible having a threaded upper portion. The holder is joined to a susceptor.

### SUMMARY OF THE INVENTION

However, in the production device of Patent Document 1, the mating surfaces of the holder for the seed substrate and the crucible correspond to surfaces extending across the upper portion of the crucible (mating surfaces 205 in FIG. 7). The mating surfaces change conduction of heat, which is likely to affect temperature distribution of the heat at the upper portion of the crucible in the lateral direction. This results in large temperature distribution in the lateral direction in the entire seed substrate held by the holder. Accordingly, SiC crystal produced is decreased in quality, disadvantageously.

The present invention is made in view of the foregoing problem, and its object is to provide a crucible, a crystal production device, and a holder, each of which allows for improved quality of produced crystal.

A crucible of the present invention includes: a body portion having a hollow inner portion; and a projection portion connected to an inner circumferential surface of the body portion and projecting toward the inner portion, the projection portion having a side surface or front surface provided with a thread.

A crystal production device of the present invention includes: the crucible; and a holder attached to the projection portion of the crucible, by the thread formed in the crucible and a thread formed in the holder.

According to the crucible and the crystal production device of the present invention, the crucible includes the projection portion having the side surface or front surface provided with the thread. At the side surface or front surface of the projection portion, the projection portion is mated with the holder for holding the seed substrate, by means of the threads respectively provided therein. This allows for reduced region in which conduction of heat is interrupted in the lateral direction of the seed substrate. Accordingly, variation of temperature distribution in the seed substrate can be restrained. This prevents thermal stress from being generated in crystal to be grown. In this way, the crystal produced is improved in quality.

Each of the crucible and the crucible in the crystal production device is preferably made of graphite. The graphite is stable at a high temperature to prevent generation of cracks in the crucible. Further, graphite is a constituent element of a SiC ingot. Hence, even if a part of the crucible is sublimated and introduced into the SiC ingot, the part thus sublimated and introduced does not become impurity. This allows for good crystallinity of the SiC ingot produced.

In the crystal production device, it is preferable that a ratio of a thermal expansion coefficient (coefficient of thermal expansion) of the projection portion of the crucible with respect to a thermal expansion coefficient of the holder is not less than 70% and not more than 130%. Accordingly, stress resulting from a difference in thermal expansion coefficient therebetween can be prevented from being exerted onto the crucible and the holder. This prevents generation of cracks in the crucible or the crystal to be produced.

Here, the ratio of the thermal expansion coefficient of the projection portion of the crucible with respect to the thermal expansion coefficient of the holder is a value determined from the following formula: (the thermal expansion coefficient of the projection portion of the crucible at a room temperature)/(the thermal expansion coefficient of the holder at the room temperature)×100(%). In the crystal production device, each of the thermal expansion coefficients of the projection portion of the crucible and the holder is preferably not less than 2.4×10⁻⁶/° C. and not more than 4.6×10⁻⁶/° C. at a room temperature.

As a result of diligent research, the present inventor has found that in the case where the above-described crystal production device is used to produce SiC crystal, by setting the respective thermal expansion coefficients of the projection portion of the crucible and the holder to fall in the above-described range, there can be reduced the difference in thermal expansion coefficient from the SiC crystal to be produced. Based on this finding, the stress resulting from the difference in thermal expansion coefficient can be prevented from being exerted to the SiC crystal produced. As such, the SiC crystal produced can be improved in crystallinity.

A holder according to one aspect of the present invention includes: a base; and a protrusion connected to an end portion of the base, the protrusion having an inner circumferential side provided with a thread.

According to the holder in the one aspect of the present invention, by means of the thread thus provided, the projection portion of the crucible can be attached to the inner circumferential side of the protrusion. As such, the protrusion of the holder serves as the mating surface of the holder with the crucible. This allows for reduced region in which the conduction of heat is interrupted in the lateral direction of the seed substrate. Accordingly, variation of temperature distribution in the seed substrate held by the holder can be restrained. This prevents generation of thermal stress in crystal to be grown on the seed substrate. In this way, the crystal produced can be improved in quality.

A holder in another aspect of the present invention includes: a base; and a thread formed on the base.

According to the holder in the another aspect of the present invention, by means of the thread thus provided on the base, the holder can be attached to the projection portion of the crucible. As such, the thread provided on the base serves as its mating surface with the crucible. This allows for reduced region in which the conduction of heat is interrupted in the lateral direction of the seed substrate. Accordingly, variation of temperature distribution in the seed substrate held by the holder can be restrained. This prevents generation of thermal stress in crystal to be grown on the seed substrate. In this way, the crystal produced can be improved in quality.

According to the crucible, the crystal production device, and the holder of the present invention, crystal produced can be improved in quality.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a crucible in a first embodiment of the present invention.

FIG. 2 is a cross sectional view schematically showing a holder in the first embodiment of the present invention.

FIG. 3 is a cross sectional view schematically showing a crystal production device in the first embodiment of the present invention.

FIG. 4 is an enlarged cross sectional view of a region A shown in FIG. 3.

FIG. 5 is a schematic diagram showing that a seed substrate and the holder are physically connected to each other in the first embodiment of the present invention.

FIG. 6 is a schematic diagram showing that the seed substrate and the holder are physically connected to each other in the first embodiment of the present invention.

FIG. 7 is a schematic diagram showing a crystal production device of Patent Document 1.

FIG. 8 is a schematic diagram showing an effect of the crystal production device in the first embodiment of the present invention.

FIG. 9 is a cross sectional view schematically showing a crucible in a second embodiment of the present invention.

FIG. 10 is a cross sectional view schematically showing a holder in the second embodiment of the present invention.

FIG. 11 is a cross sectional view schematically showing a crystal production device in the second embodiment of the present invention.

### DESCRIPTION OF THE PREFERRED EMBODIMENTS

The following describes embodiments of the present invention with reference to figures. It should be noted that the same or corresponding portions are given the same reference characters and are not described repeatedly.

### First Embodiment

FIG. 1 is a cross sectional view schematically showing a crucible in a first embodiment of the present invention. Referring to FIG. 1, a crucible 100 of the present embodiment will be described first. Crucible 100 of the present embodiment is used in growing SiC crystal by means of a sublimation method.

As shown in FIG. 1, crucible 100 has a body portion 101 having a hollow inner portion, and a projection portion 102 connected to an inner circumferential surface of body portion 101 and projecting toward the inner portion thereof.

Body portion 101 has, for example, a tubular shape with closed upper and lower ends. Body portion 101 has a lower portion at which a raw material is to be placed.

Projection portion 102 is formed to project downward (in the present embodiment, in a direction orthogonal to the inner circumferential surface on which projection portion 102 is formed) from the upper inner circumferential surface of body portion 101. In projection portion 102, a seed substrate is placed using a holder. Hence, projection portion 102 has its wall surface with a portion opposite to and projecting toward the raw material. Projection portion 102 does not extend to reach the opposite inner circumferential surface of body portion 101 (in the present embodiment, the lower inner circumferential surface thereof). It should be noted that projection portion 102 may project toward the inner portion from an inner circumferential surface of body portion 101 other than the upper inner circumferential surface thereof.

Projection portion 102 has a side surface provided with a thread 102a. In the present embodiment, thread 102a is formed at a lower side in the entire circumference of the side surface of projection portion 102.

Body portion 101 and projection portion 102 are formed, for example, in one piece, and is made of graphite. Projection portion 102 preferably has a thermal expansion coefficient of not less than 2.4×10⁻⁶/° C. and not more than 4.6×10⁻⁶/° C. at a room temperature. In this case, since such a projection portion 102 is connected to the holder for holding the seed substrate, there can be reduced a difference in thermal expansion coefficient from SiC crystal produced in crucible 100.

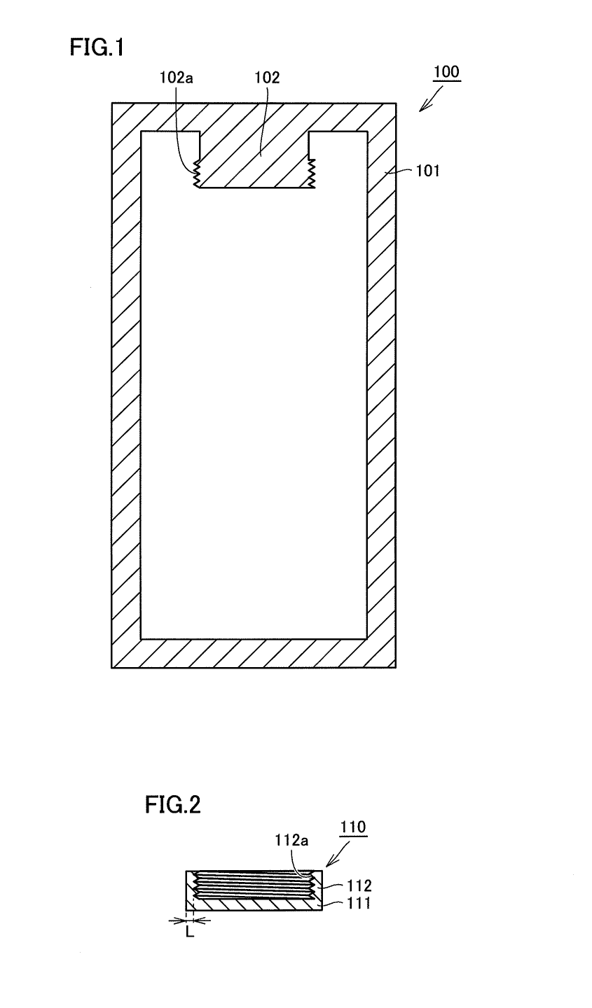

FIG. 2 is a cross sectional view schematically showing the holder in the first embodiment of the present invention. Now, referring to FIG. 2, holder 110 in the present embodiment will be described. Holder 110 of the present embodiment is a member for holding the seed substrate.

As shown in FIG. 2, holder 110 includes a base 111, and a protrusion 112 connected to the end portion of base 111.

Base 111 is, for example, in the form of a plate. At the end portion of base 111, protrusion 112 is formed to extend in a direction crossing a direction in which base 111 extends (in the present embodiment, direction orthogonal to the direction in which base 111 extends). Protrusion 112 is not particularly limited as long as it is formed at the end portion of base 111, but is preferably formed at the end of base 111.

Protrusion 112 has an inner circumferential side provided with a thread 112a. In other words, thread 112a is formed therein at a region surrounded by base 111 and protrusion 112.

Protrusion 112 has a width L of, for example, 1 mm or greater. In this case, strength of protrusion 112 can be secured.

Base 111 and protrusion 112 are formed, for example, in one piece, and are made of graphite. Each of base 111 and protrusion 112 preferably has a thermal expansion coefficient of for example, not less than 2.4×10⁻⁶/° C. and not more than 4.6×10⁻⁶/° C. at the room temperature. In this case, since such a holder 110 holds the seed substrate, there can be reduced a difference in thermal expansion coefficient from SiC crystal produced in crucible 100 to which holder 110 is attached.

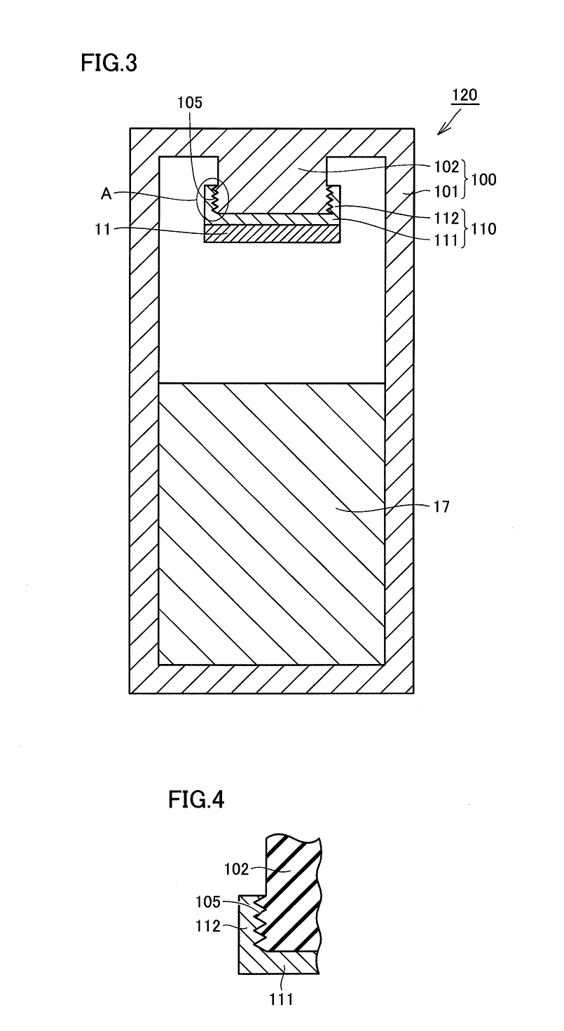

FIG. 3 is a cross sectional view schematically showing a crystal production device in the first embodiment of the present invention. FIG. 4 is an enlarged cross sectional view of a region A in FIG. 3. Now, referring to FIG. 3 and FIG. 4, a crystal production device 120 in the present embodiment will be described.

Crystal production device 120 includes crucible 100 shown in FIG. 1 and holder 110 shown in FIG. 2. Holder 110 is attached to projection portion 102 of crucible 100 by means of the threads. In the present embodiment, thread 102a formed in projection portion 102 of crucible 100 is engaged with thread 112a formed in protrusion 112 of holder 110. In other words, holder 110 and projection portion 102 provided in crucible 100 are attached to each other by means of their threads. For example, thread 102a is an external thread whereas thread 112a is an internal thread. Surfaces thereof at which threads 102a, 112a are mated are regarded as “mating surfaces 105”.

A ratio of the thermal expansion coefficient of projection portion 102 of crucible 100 with respect to the thermal expansion coefficient of holder 110 is preferably not less than 70% and not more than 130%. Further, the thermal expansion coefficient of projection portion 102 of crucible 100 is preferably in a range of not less than 2.4×10⁻⁶/° C. and not more than 4.6×10⁻⁶/° C. at the room temperature. In this case, upon producing crystal, projection portion 102 and holder 110 are prevented from receiving stress resulting from a difference in thermal expansion coefficient therebetween. This prevents generation of cracks in projection portion 102 of crucible 100 and protrusion 112 of holder 110, thus preventing generation of cracks in the crucible and the inner portion of an ingot.

Here, the term “difference (ratio) in thermal expansion coefficient” refers to a value determined from the following formula: (the thermal expansion coefficient of projection portion 102 of crucible 100 at the room temperature)/(the thermal expansion coefficient of holder 110 at the room temperature)×100(%).

The following describes a method for producing crystal in the present embodiment, with reference to FIG. 1-FIG. 3. The method for producing crystal in the present embodiment utilizes crystal production device 120 shown in FIG. 3 and FIG. 4, which includes crucible 100 shown in FIG. 1 and holder 110 shown in FIG. 2. In the present embodiment, SiC crystal is produced using the sublimation method.

First, as shown in FIG. 3, a raw material 17 is placed in the inner portion of body portion 101 of crucible 100. In the present embodiment, raw material 17 is placed at the lower portion of the body portion 101 of crucible 100. Raw material 17 may be a powder or a sintered compact, and may be a polycrystalline SiC powder or a SiC sintered compact, for example.

Then, as shown in FIG. 3, seed substrate 11 is placed on holder 110 in the inner portion of body portion 101 of crucible 100. In the present embodiment, seed substrate 11 is placed at the upper portion of crucible 100 so as to be opposite to raw material 17 in crucible 100.

Seed substrate 11 thus prepared is not particularly limited in crystal structure, and may have the same crystal structure as that of SiC crystal to be grown or have a crystal structure different therefrom. To improve crystallinity of the SiC crystal to be grown, SiC crystal having the same crystal structure is preferably prepared as seed substrate 11.

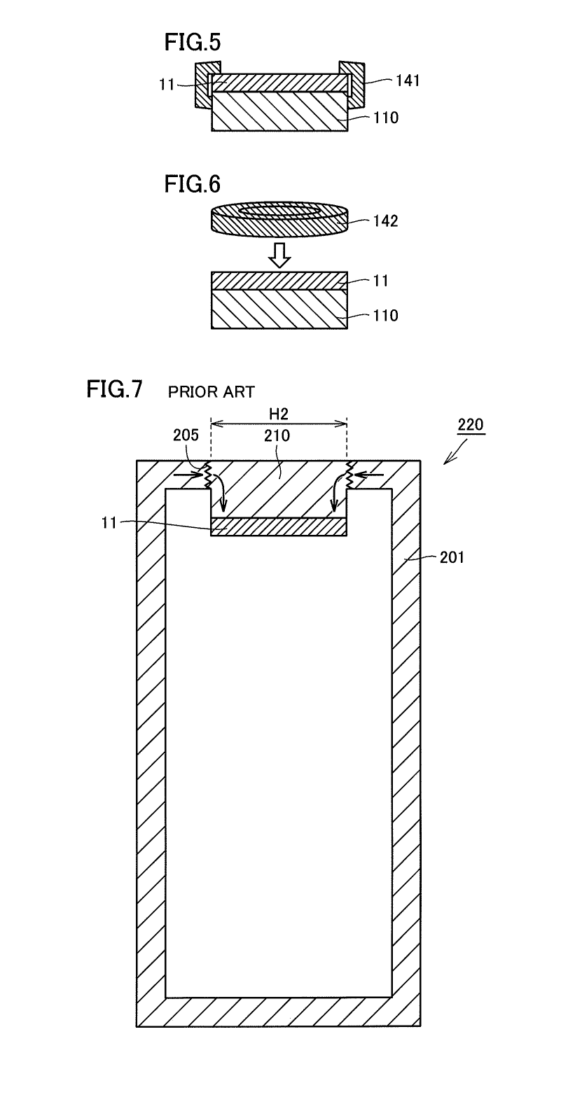

A method for placing seed substrate 11 onto holder 110 is not particularly limited, but for example, seed substrate 11 and holder 110 may be physically connected to each other using fixing members 141, 142 shown in FIG. 5 and FIG. 6, or seed substrate 11 and holder 110 may be connected to each other using an adhesive agent. FIG. 5 and FIG. 6 are schematic diagrams showing states in which seed substrate 11 and holder 110 are physically connected to each other in the first embodiment of the present invention.

In connecting them physically, for example, a finger made of graphite may be used as fixing member 141 as shown in FIG. 5. Alternatively, as shown in FIG. 6, a cap made of graphite may be used as fixing member 142.

In the case of using the adhesive agent, the adhesive agent preferably includes a resin formed into non-graphitizable carbon when being carbonized through heating, heat-resistant fine particles, and a solvent. More preferably, the adhesive agent further includes a carbohydrate.

The resin formed into non-graphitizable carbon is, for example, a novolak resin, a phenol resin, or a furfuryl alcohol resin.

The heat-resistant fine particles have a function of increasing a filling rate in a fixation layer formed by heating the adhesive agent at a high temperature, by uniformly distributing the above-described non-graphitizable carbon in the fixation layer. The heat-resistant fine particles can be formed of a heat-resistant material such as carbon (C) like graphite, SiC, boron nitride (BN), or aluminum nitride (AlN). Apart from these materials, a refractory metal or a compound of a carbide or nitride thereof can be used. A usable exemplary refractory metal is tungsten (W), tantalum (Ta), molybdenum (Mo), titanium (Ti), zirconium (Zr), or hafnium (Hf). Each of the heat-resistant fine particles has a particle diameter of, for example, 0.1-10 μm.

As the carbohydrate, there can be used a saccharide or a derivative thereof. The saccharide may be a monosaccharide such as glucose or a polysaccharide such as cellulose.

As the solvent, a solvent can be appropriately selected which is capable of dissolving and dispersing the above-described resin and carbohydrate. Further, the solvent is not limited to a solvent including only one type of liquid, but may include a mixed liquid of a plurality of types of liquids. For example, a solvent may be used which includes alcohol for dissolving the carbohydrate, and cellosolve acetate for dissolving the resin.

In the case where such an adhesive agent is used, the adhesive agent is placed between seed substrate 11 and holder 110 and is then heated. Accordingly, the adhesive agent is cured to form the fixation layer, thus fixing seed substrate 11 and holder 110 to each other.

Next, in crucible 100, raw material 17 is heated to be sublimated so as to deposit a source gas onto seed substrate 11, thereby growing SiC crystal thereon.

Specifically, raw material 17 is heated by a heating unit to a temperature at which raw material 17 is sublimated. By the heating, raw material 17 is sublimated to generate a sublimation gas. The sublimation gas is solidified on the surface of seed substrate 11. The surface of seed substrate 11 is set at a temperature lower than that of raw material 17. Exemplary temperatures for growth are as follows: the temperature of raw material 17 is maintained at 2300° C.-2400° C. and the temperature of seed substrate 11 is maintained at 2100° C.-2200° C. This allows SiC crystal to grow on seed substrate 11. The temperatures for growth may be maintained at constant temperatures during the growth or may be changed at a certain rate during the growth.

Then, the inner portion of crucible 100 is cooled down to the room temperature. Then, from crucible 100, a produced SiC ingot is taken out which includes seed substrate 11 and the SiC crystal grown on seed substrate 11. In this way, the SiC crystal can be produced.

It should be noted that the method for producing SiC crystal is illustrated in the present embodiment, but the crystal produced in the present invention is not limited to SiC crystal and is applicable to MN crystal, GaN (gallium nitride) crystal, and the like, for example.

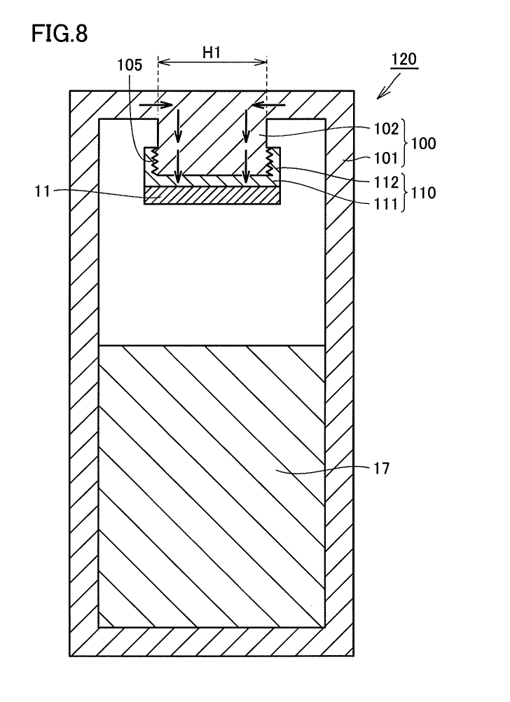

The following describes effects provided by crucible 100, holder 110, and crystal production device 120 shown in FIG. 1-FIG. 4 and FIG. 8 in the present embodiment, in comparison to the foregoing crystal production device of Patent Document 1 in FIG. 7. FIG. 7 is a schematic diagram showing the crystal production device 220 of Patent Document 1. FIG. 8 is a schematic diagram showing an effect provided by crystal production device 120 in the first embodiment of the present invention. Arrows in FIG. 7 and FIG. 8 represent conduction of heat in the vicinity of seed substrate 11.

In crystal production device 220 of Patent Document 1 in FIG. 7, the threads are provided in the upper portion of crucible 201 and the upper portion of holder 210 respectively. When holder 210 and crucible 201 are connected to each other by means of these threads, mating surfaces 205 of holder 210 and crucible 201 correspond to the surfaces extending across the upper portion of crucible 201. There is a slight space between mating surfaces 205 because they are attached to each other by means of the threads. Accordingly, the conduction of heat is interrupted at mating surfaces 205, thereby changing the conduction of heat at a region H2 extending in the lateral direction in the upper portion of crucible 201. Specifically, in crystal production device 220, temperature distribution becomes large entirely in the lateral direction of seed substrate 11. As a result, produced SiC crystal is decreased in quality, disadvantageously.

In contrast, crystal production device 120 of the present embodiment includes crucible 100 including projection portion 102 projecting toward the inner portion and having thread 102a at the side surface of projection portion 102, and holder 110 attached to projection portion 102 of crucible 100 by means of thread 112a.

The side surface of projection portion 102 of crucible 100 is mated with holder 110 for holding seed substrate 11, so the conduction of heat is not interrupted until mating surfaces 105 as shown in FIG. 8. Thus, a region in which the conduction of heat is interrupted in the lateral direction of seed substrate 11 (i.e., region influenced by mating surfaces 105) corresponds to a region H1 shown in FIG. 8. Region H1 in the present embodiment, in which the conduction of heat is influenced by the mating of crucible 100 and holder 110, is smaller than region H2 in crystal production device 220 of FIG. 7, i.e., region H2 in which the conduction of heat is influenced by the mating of crucible 201 and holder 210. This achieves reduced influence of interruption of the conduction of heat over seed substrate 11 in the present embodiment. Accordingly, variation of temperature distribution in seed substrate 11 can be restrained. This restrains generation of thermal stress in the crystal to be grown. Hence, the crystal produced is improved in quality.

Further, since crucible 100 and holder 110 can be connected to each other by means of the threads, the installation position of seed substrate 11 can be controlled readily. In other words, a distance between seed substrate 11 and raw material 17 can be controlled. Thus, crystal can be produced according to various conditions for growth.

### Second Embodiment

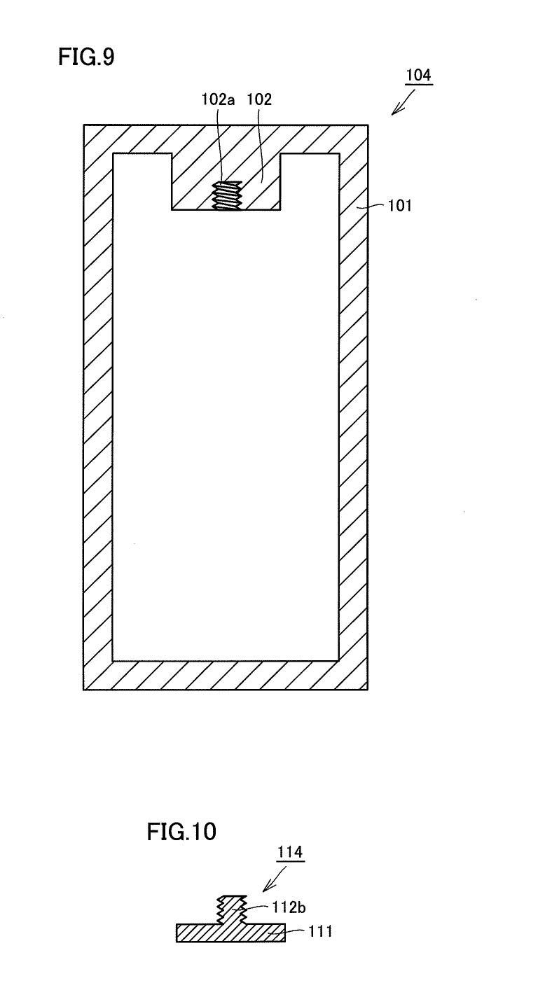

FIG. 9 is a cross sectional view schematically showing a crucible in a second embodiment of the present invention. Referring to FIG. 9, a crucible 104 in the present embodiment will be described. Crucible 104 in the present embodiment basically has a configuration similar to that of crucible 100 of the first embodiment in FIG. 1, but is different therefrom in that thread 102a is provided in the front surface of projection portion 102.

Specifically, thread 102a is formed at the center of the front surface (surface on which the holder is attached) of projection portion 102 so as to extend toward body portion 101 to which projection portion 102 is connected. Namely, thread 102a is formed in a recess formed in the front surface of projection portion 102. Thread 102a does not extend to reach body portion 101.

FIG. 10 is a cross sectional view schematically showing a holder 114 of the second embodiment of the present invention. Now, referring to FIG. 10, holder 114 in the present embodiment will be described. Holder 114 in the present embodiment basically has a configuration similar to that of holder 110 of the first embodiment in FIG. 2, but is different therefrom in that a thread 112b is formed instead of protrusion 112.

Specifically, holder 114 of the present embodiment includes a base 111, and thread 112b formed on base 111. Thread 112b protrudes from the center of the surface of base 111 in a direction crossing a direction in which the surface of base 111 extends (direction orthogonal to the surface of base 111 in the present embodiment). In base 111, the surface on which thread 112b is formed is a surface to be attached to crucible 104, and is located opposite to its surface (flat surface) for holding seed substrate 11.

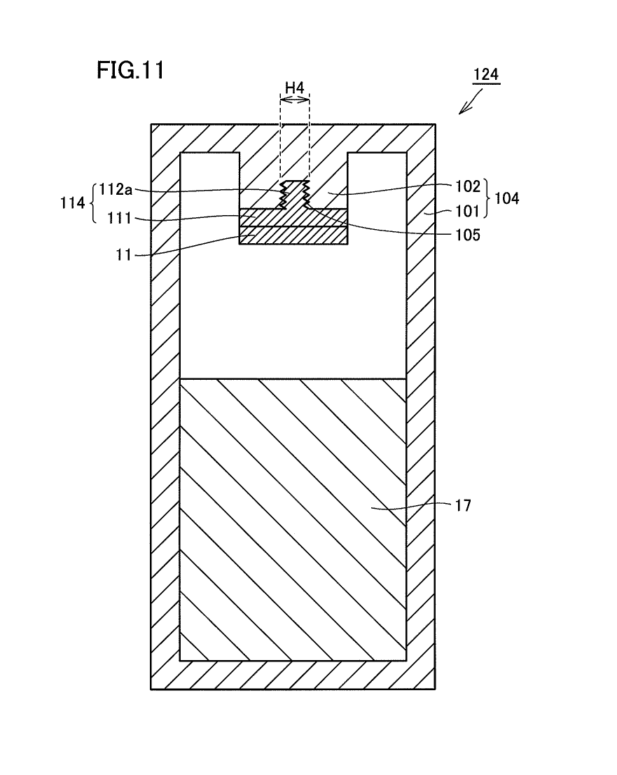

FIG. 11 is a cross sectional view schematically showing a crystal production device 124 of the second embodiment of the present invention. Referring to FIG. 11, crystal production device 124 in the present embodiment will be described. Crystal production device 124 in the present embodiment basically has a configuration similar to that of crystal production device 120 of the first embodiment in FIG. 3, but is different therefrom in that crucible 104 and holder 114 are mated by means of thread 102a formed in the front surface of projection portion 102 of crucible 104, and thread 112b formed on base 111 of holder 114.

In crystal production device 124 of the present embodiment, a region in which the conduction of heat is interrupted corresponds to a region H4 in FIG. 11. As such, crucible 104, holder 114, and crystal production device 124 in the present embodiment allow for reduced variation in temperature distribution in the lateral direction of seed substrate 11, as compared with crystal production device 220 shown in FIG. 7. This restrains generation of thermal stress in crystal to be grown. Accordingly, crystal produced can be improved in quality.

### EXAMPLE

Inspected in the present example was an effect attained by providing the crucible having the thread at the side surface or front surface of the projection portion, and the holder. Also inspected was an effect resulting from a difference in thermal expansion coefficient between the projection portion of the crucible and the holder in this crystal production device.

### The Present Invention's Examples 1-4

In each of the present invention's examples 1-4, crucible 100 having the structure shown in FIG. 1, and holder 110 having the structure shown in FIG. 2 were prepared. Crucible 100 and holder 110 were attached to each other by means of threads 102a, 112a, thereby preparing crystal production device 120 shown in FIG. 3.

Employed as a material for each of body portion 101 and projection portion 102 of crucible 100 was graphite having a thermal expansion coefficient of 2.4×10⁻⁶/° C. to 4.6×10⁻⁶/° C. at the room temperature. Employed as a material for each of base 111 and protrusion 112 of holder 110 was graphite having a thermal expansion coefficient of 2.4×10⁻⁶/° C. to 4.6×10⁻⁶/° C. at the room temperature. Table 1 below shows a ratio of the thermal expansion coefficient of the projection portion of the crucible with respect to the thermal expansion coefficient of the holder (value determined by (the thermal expansion coefficient of projection portion 102 of crucible 100 at the room temperature)/(the thermal expansion coefficient of holder 110 at the room temperature)×100(%)). It should be noted that in Table 1, the thermal expansion coefficients of crucible 100 and holder 110 were values at the room temperature. It should be also noted that protrusion 112 of holder 110 had a width (width L in FIG. 2) of 2 mm.

Such a crystal production device 120 was used to produce SiC crystal. As seed substrate 11, a two-inch SiC substrate was prepared. Seed substrate 11 thus prepared was attached to base 111 of holder 110, and then was placed on the upper portion of crucible 100. Then, as raw material 17, SiC powders were placed at the lower portion of the inner portion of body portion 101 of crucible 100 so as to be opposite to seed substrate 11.

Next, temperature in crucible 100 was increased using a heating unit. The increasing of temperature was controlled so that temperature at the raw material 17 side in crucible 100 was 2300° C. whereas temperature at the seed substrate 11 side was 2100° C. On this occasion, pressure in crucible 100 was set at 100 Torr or smaller. With such settings, raw material 17 was sublimated to obtain SiC gas. With growth time set at 30 hours, SiC crystal was grown on seed substrate 11. Thereafter, the temperature in the inner portion of crystal production device 120 was cooled down to the room temperature. In this way, a two-inch SiC crystal piece (ingot) having a thickness of 30 mm was produced. Intended crystal polymorphism (polytype) of the SiC crystal was 4H—SiC.

### Comparative Example 1

In a comparative example 1, SiC crystal was produced basically in the same manner as in the present invention's example 1, except that crystal production device 220 including crucible 201 and holder 210 as shown in FIG. 7 was used.

(Measuring Method)

Ten pieces of SiC crystal (ingots) were produced using each of the crystal production devices of the present invention's examples 1-4 and comparative example 1. The respective curvature radii of the ingots were measured and the average values thereof were determined.

Further, each of the ingots was sliced to obtain forty SiC substrates. Each of the SiC substrates was surface-polished, and then was soaked in a KOH (potassium hydroxide) melt of 500° C. for 1-10 minutes. Then, micropipe density in the surface thus etched was counted using a Nomarski differential interference microscope. A value determined from the following formula “(the measured value thereof)/(the micropipe density of seed substrate)×100” was regarded as a micropipe reduction ratio.

Meanwhile, each of the SiC substrates obtained through the slicing was observed with visual inspection so as to check whether or not polytype other than 4H—SiC had been generated. It was judged that polytype other than 4H—SiC was generated (anomaly in polytype), when there existed one substrate different in color. When there was an anomaly in polytype in each of the SiC ingots, it was judged that the ingot had a different polytype, and a ratio was found by dividing, by 10, the number of ingots judged to have anomaly in polytype among the ten ingots grown under the same condition (i.e., generation ratio of the intended polytype). The ratio thus found was regarded as “polytype generation ratio”.

In addition, in the present invention's examples 1-4, after producing the ingots, each of the ingots was sliced into the form of wafers. Then, whether or not there were cracks in the wafers was checked with visual inspection. Then, a probability of occurrence of cracked wafers in all the wafers was determined.

Results of these are shown in Table 1 below.

TABLE 1

| | Thermal | | | | |
|---|---|---|---|---|---|
| | Expansion | | | | |
| | Coefficient | | | | |
| | of | | | | |
| | Projection | | | | |
| | Portion of | | | | |
| | Crucible/ | | | | |
| | Thermal | | | Polytype | Crack |
| | Expansion | | Micropipe | Genera- | Genera- |
| | Coefficient | Curvature | Reduction | tion | tion |
| | of Holder × | Radius | Ratio | Ratio | Ratio |
| | 100 (%) | (Mm) | (%) | (%) | (%) |
| The Present | 135 | 100-150 | 50-80 | 50 | 15 |
| Invention's | | | | | |
| Example 1 | | | | | |
| The Present | 130 | 500-1000 | 10-20 | 10 | 0 |
| Invention's | | | | | |
| Example 2 | | | | | |
| The Present | 70 | 500-1000 | 10-20 | 10 | 0 |
| Invention's | | | | | |
| Example 3 | | | | | |
| The Present | 67 | 100-150 | 50-80 | 40 | 20 |
| Invention's | | | | | |
| Example 4 | | | | | |
| Comparative | 60 | 50-100 | 60-85 | 60 | 35 |
| Example 1 | | | | | |

(Measurement Result)

As shown in Table 1, the SiC crystal produced using the crucible, the holder, and the crystal production device of each of the present invention's examples 1-4 was more excellent in terms of curvature radius, micropipe, polytype, and crack than the SiC crystal produced using crucible 201, holder 210, and crystal production device 220 of comparative example 1, because reduced temperature distribution was achieved in the seed substrate. From this fact, it was confirmed that crystal produced can be improved in quality using the crystal production device of the present invention, i.e., the crystal production device including the crucible having the thread at the side surface or front surface of the projection portion, and the holder having the threaded portion in the present invention.

Further, the crack generation ratio was 0% in the SiC crystal produced using crystal production device 120 of the present invention's example 3 in which the ratio of the thermal expansion coefficient of projection portion 102 of crucible 100 with respect to the thermal expansion coefficient of holder 110 was 70%. The crack generation ratio was also 0% in the SiC crystal produced using crystal production device 120 of the present invention's example 2 in which the ratio thereof was 130%. From this result, it is appreciated that generation of cracks can be restrained in the produced SiC crystal when the ratio of the thermal expansion coefficient of projection portion 102 of crucible 100 with respect to the thermal expansion coefficient of holder 110 is not less than 70% and not more than 130%.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A crucible comprising:
a body portion having a hollow inner portion; and
a projection portion connected to an inner circumferential surface of said body portion and projecting toward the inner portion,
said projection portion having a side surface or front surface provided with a thread.

2. The crucible according to claim 1, wherein said crucible is made of graphite.

3. A crystal production device comprising:
the crucible according to claim 1; and
a holder attached to said projection portion of said crucible, by the thread formed in the crucible and a thread formed in the holder.

4. The crystal production device according to claim 3, wherein a ratio of a thermal expansion coefficient of said projection portion of said crucible with respect to a thermal expansion coefficient of said holder is not less than 70% and not more than 130%.

5. The crystal production device according to claim 3, wherein each of the thermal expansion coefficients of said projection portion of said crucible and said holder is not less than 2.4×10⁻⁶/° C. and not more than 4.6×10⁻⁶/° C. at a room temperature.

6. A holder comprising:
a base; and
a protrusion connected to an end portion of said base,
said protrusion having an inner circumferential side provided with a thread.

7. A holder comprising:
a base; and
a thread formed on said base.
